(19) United States
(12) Patent Application Publication
(10) Pub. No.: US 2015/0364539 A1
(43) Pub. Date: Dec. 17, 2015

(54) PACKAGE BOARD AND PACKAGE USING THE SAME

(71) Applicant: SAMSUNG ELECTRO-MECHANICS CO., LTD., Suwon-Si (KR)

(72) Inventors: Se Rang IM, Suwon-Si (KR); Seung Eun LEE, Suwon-Si (KR); Seung Yeop KOOK, Suwon-Si (KR); Myung Sam KANG, Suwon-Si (KR)

(73) Assignee: SAMSUNG ELECTRO-MECHANICS CO., LTD., Suwon-Si (KR)

(21) Appl. No.: 14/585,183

(22) Filed: Dec. 30, 2014

(30) Foreign Application Priority Data
Jun. 12, 2014 (KR) 10-2014-0071611

(51) Int. Cl. H01L 49/02; H01L 23/498

(52) U.S. Cl. CPC H01L 28/60; H01L 23/49827

(57) ABSTRACT

There are provided a package board and a package using the same. The package board according to an exemplary embodiment of the present disclosure includes: an insulating layer; a dielectric layer formed on the insulating layer; a lower electrode formed on a whole surface of an upper surface of the insulating layer; and an upper electrode formed on a whole surface of an upper surface of the dielectric layer.

### CROSS-REFERENCE TO RELATED APPLICATION

This application claims the foreign priority benefit of Korean Patent Application No. 10-2014-0071611, filed on Jun. 12, 2014, entitled “Package Board and Package Using the Same” which is hereby incorporated by reference in its entirety into this application.

### BACKGROUND

Embodiments of the present disclosure relates to a package board and a package using the same.

An electronic industry has recently adopted a mounting technology using a multi-layer printed circuit board capable of implementing high densification and high integration upon mounting components in order to implement miniaturization and thinness of an electronic device.

A package on package (POP) in which an application process and a memory device are implemented as a single package form has been used to miniaturize most high performance smart phones and improve performance thereof As the application process and the memory device are gradually implemented as high performance, an aspect for improving electrical characteristics of a board configuring the POP has been studied.

[Related Art Document]

[Patent Document]

(Patent Document 1) U.S. Pat. No. 5,986,209

### SUMMARY

An aspect of the present disclosure may provide a package board having a capacitor of large capacitance and a package using the same.

An aspect of the present disclosure may also provide a package board capable of reducing an occurrence of warpage and a package using the same.

An aspect of the present disclosure may also provide a package board capable of improving reliability of a signal transmission and a package using the same.

According to an aspect of the present disclosure, a package board may include: an insulating layer; a dielectric layer formed on the insulating layer; a lower electrode formed on a whole surface of an upper surface of the insulating layer; and an upper electrode formed on a whole surface of an upper surface of the dielectric layer.

The package board may further include an inner layer circuit pattern formed in the insulating layer and a first via formed in the insulating layer to thereby electrically connect the inner layer circuit pattern and the lower electrode to each other.

The package board may further include a first outer layer circuit pattern formed on the upper surface of the dielectric layer to be spaced apart from the upper electrode and a second via formed in the insulating layer to thereby electrically connect the inner layer circuit pattern and the first outer layer circuit pattern. The second via may have side surfaces formed to be spaced apart from the lower electrode.

The package board may further include a second outer layer circuit pattern formed on a lower surface of the insulating layer and a third via formed in the insulating layer to thereby electrically connect the second outer layer circuit pattern and the lower electrode to each other.

The package board may further include a fourth via formed in the insulating layer and the dielectric layer to thereby electrically connect the second outer layer circuit pattern and the upper electrode. The fourth via may have side surfaces formed to be spaced apart from the lower electrode.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is an illustrative view showing a package board according to a first exemplary embodiment of the present disclosure;

FIGS. 2 through 12 are illustrative views showing a method of manufacturing a package board according to the first exemplary embodiment of the present disclosure;

FIG. 13 is an illustrative view showing a package board according to a second exemplary embodiment of the present disclosure;

FIGS. 14 through 22 are illustrative views showing a method of manufacturing a package board 200 according to the second exemplary embodiment of the present disclosure;

FIG. 23 is an illustrative view showing a package board according to a third exemplary embodiment of the present disclosure;

FIGS. 24 through 30 are illustrative views showing a method of manufacturing a package board according to the third exemplary embodiment of the present disclosure;

FIG. 31 is an illustrative view showing a package board according to a fourth exemplary embodiment of the present disclosure;

FIGS. 32 through 37 are illustrative views showing a method of manufacturing a package board according to the fourth exemplary embodiment of the present disclosure; and

FIG. 38 is an illustrative view showing a package formed using the package board according to the first exemplary embodiment of the present disclosure.

### DETAILED DESCRIPTION

The objects, features and advantages of the present disclosure will be more clearly understood from the following detailed description of the exemplary embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present disclosure, when it is determined that the detailed description of the related art would obscure the gist of the present disclosure, the description thereof will be omitted.

Hereinafter, exemplary embodiments of the present disclosure will be described in detail with reference to the accompanying drawings.

### First Exemplary Embodiment

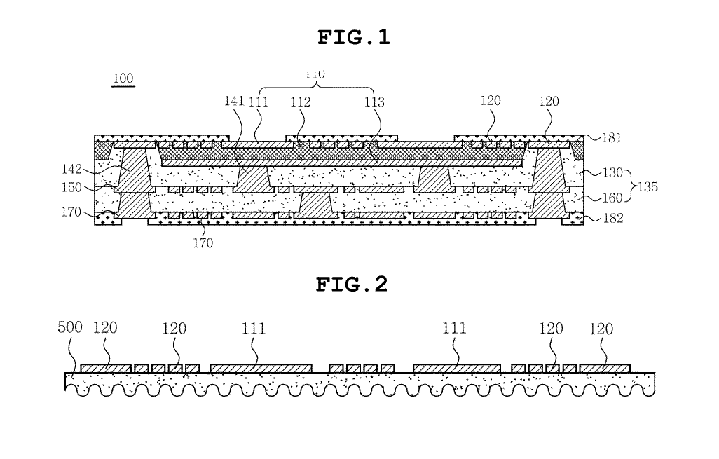

FIG. 1 is an illustrative view showing a package board according to a first exemplary embodiment of the present disclosure.

Referring to FIG. 1, the package board 100 according to a first exemplary embodiment of the present disclosure includes an insulating layer 135, an inner layer circuit pattern 150, and a capacitor 110. In addition, the package board 100 may further include a first outer layer circuit pattern 120, a second outer layer circuit pattern 170, a first via 141, a second via 142, a first protecting layer 181, and a second protecting layer 182.

The insulating layer 135 according to an exemplary embodiment of the present disclosure may be classified into a first insulating layer 130 and a second insulating layer 160 formed below the first insulating layer 130. Here, since the insulating layer 135 is merely classified into the first insulating layer 130 and the second insulating layer 160 for convenience of explanation, functions, materials, or the like of the respective insulating layers are not different. In addition, although an exemplary embodiment of the present disclosure describes the insulating layer having a two-layer structure, this is only an illustration, and the number of layers of the insulating layer 135 may be changed according to a selection of those skilled in the art.

According to an exemplary embodiment of the present disclosure, the first insulating layer 130 and the second insulating layer 160 may be made of a complex polymer resin typically used as an interlayer insulating material. For example, the first insulating layer 130 and the second insulating layer 160 may be made of a prepreg, Ajinomoto Build up Film (ABF), and an epoxy based resin such as FR-4, Bismaleimide Triazine (BT), or the like. However, the material forming the first insulating layer 130 and the second insulating layer 160 according to an exemplary embodiment of the present disclosure is not limited thereto. The first insulating layer 130 and the second insulating layer 160 may be selected from insulating materials known in the field of circuit board.

In addition, according to an exemplary embodiment of the present disclosure, a portion of the first insulating layer 130 may be formed so as to penetrate through a dielectric layer 112.

According to an exemplary embodiment of the present disclosure, the capacitor 110 includes the dielectric layer 112, a lower electrode 113, and an upper electrode 111. In addition, the capacitor 110 has a structure in which the dielectric layer 112 is interposed between the upper electrode 111 and the lower electrode 113.

According to an exemplary embodiment of the present disclosure, the dielectric layer 112 is formed on the first insulating layer 130. The dielectric layer 112 may be made of any material of dielectric materials used in a capacitor field.

In addition, according to an exemplary embodiment of the present disclosure, the lower electrode 113 is formed on a whole surface of an upper surface of the first insulating layer 130 and is formed to be buried in the first insulating layer 130. That is, the lower electrode 113 is formed so that side surfaces and a lower surface thereof are positioned in the first insulating layer 130 and an upper surface thereof is exposed to the outside of the first insulating layer 130.

In addition, according to an exemplary embodiment of the present disclosure, the upper electrode 111 is formed on a whole surface of an upper surface of the dielectric layer 112 and is formed to be buried in the dielectric layer 112. That is, the upper electrode 111 is formed so that side surfaces and a lower surface thereof is positioned in the dielectric layer 112 and an upper surface thereof is exposed to the outside of the dielectric layer 112.

The lower electrode 113 and the upper electrode 111 according to an exemplary embodiment of the present disclosure are made of a conductive material. For example, the lower electrode 113 and the upper electrode 111 may be made of copper (Cu). However, a material of the lower electrode 113 and the upper electrode 111 is not limited to copper and any material may be used as long as it is used as an electrode in the capacitor field.

As such, according to an exemplary embodiment of the present disclosure, since the capacitor 110 is formed on the outermost layer of the package board 100 to thereby decrease a signal transmission distance with electronic components (not shown) to be mounted later, a signal transmission speed may be improved. In addition, since the capacitor 110 is formed on a whole surface of the package board 100, capacitance of the capacitor 110 may be increased. Since the capacitor 110 has large capacitance, a noise blocking function may be improved and reliability in signal transmission may be improved. In addition, since the capacitor 110 is formed on the whole surface of the package board 100, an occurrence of warpage of the package board 100 may be decreased.

According to an exemplary embodiment of the present disclosure, the inner layer circuit pattern 150 is formed in the insulating layer 135. For example, the inner layer circuit pattern 150 may be formed so as to be formed on the second insulating layer 160 and buried in the first insulating layer 130. A position in which the inner layer circuit pattern 150 is formed as described above is merely an illustration of the present disclosure, and is not limited thereto. That is, the position in which the inner layer circuit pattern 150 is formed may be changed according to a selection of those skilled in the art. The inner layer circuit pattern 150 according to an exemplary embodiment of the present disclosure may be made of a conductive material used in a field of circuit board. For example, the inner layer circuit pattern 150 may be made of copper.

According to an exemplary embodiment of the present disclosure, the first via 141 electrically connecting the inner layer circuit pattern 150 and the lower electrode 113 of the capacitor 110 may be formed. For example, the first via 141 is formed to penetrate through the first insulating layer 130, such that a lower surface thereof may be bonded to the inner layer circuit pattern 150 and an upper surface thereof may be bonded to the lower electrode 113 of the capacitor 110. The first via 141 according to an exemplary embodiment of the present disclosure may be made of a conductive material used in a field of circuit board such as copper.

According to an exemplary embodiment of the present disclosure, the first outer layer circuit pattern 120 may be formed on the upper surface of the dielectric layer 112. In this case, the first outer layer circuit pattern 120 may be formed to be buried in the dielectric layer 112 and have side surfaces formed to be spaced apart from the upper electrode 111, similar to the upper electrode 111. As first outer layer circuit pattern 120 is formed, the upper electrode 111 of the capacitor 110 may be formed on a region in which the first outer layer circuit pattern 120 is not formed among the upper surface of the dielectric layer 112. However, according to an exemplary embodiment of the present disclosure, the entire first outer layer circuit pattern 120 is not formed on the dielectric layer 112. As shown in FIG. 1, the first outer layer circuit pattern 120 connected to the second via 142 may be formed in the first insulating layer 130 penetrating through the dielectric layer 112.

In addition, according to an exemplary embodiment of the present disclosure, the second outer layer circuit pattern 170 may be formed on the lower surface of the second insulating layer 160. In this case, the second outer layer circuit pattern 170 may be formed in a structure protruded from the lower surface of the second insulating layer 160. In addition, the second outer layer circuit pattern 170 may include an external connecting pad electrically connected to an external configuring unit.

The first outer layer circuit pattern 120 and the second outer layer circuit pattern 170 according to an exemplary embodiment of the present disclosure may be made of a conductive material used in the field of circuit board such as copper.

According to an exemplary embodiment of the present disclosure, the second via 142 may be formed in the first insulating layer 130 to electrically connect the inner layer circuit pattern 150 and the first outer layer circuit pattern 120 to each other. For example, the second via 142 is formed in the first insulating layer 130 penetrating through the dielectric layer 112, such that an upper surface thereof may be bonded to the first outer layer circuit pattern 120 and a lower surface thereof may be bonded to the inner layer circuit pattern 150. The second via 142 according to an exemplary embodiment of the present disclosure may be made of a conductive material used in a field of circuit board such as copper.

In addition, although not described in detail in an exemplary embodiment of the present disclosure, a via formed in the second insulating layer 160 and electrically connecting the second outer layer circuit pattern 170 and the inner layer circuit pattern 150 to each other may be further formed. In addition, although not shown, the inner layer circuit pattern having a plurality of layers may be formed in the package board 100. In this case, it is apparent that vias electrically connecting the respective layers to each other may be further formed.

According to an exemplary embodiment of the present disclosure, the first protecting layer 181 may be formed on the dielectric layer 112, the upper electrode 111, and the first outer layer circuit pattern 120. The first protecting layer 181 is formed to protect the upper electrode 111 and the first outer layer circuit pattern 120 from the outside. In this case, the first protecting layer 181 is formed to expose a potion of the upper electrode 111 of the capacitor 110. Here, the portion of the upper electrode 111 exposed by the first protecting layer 181 is a portion electrically connected to the external configuring unit such as electronic components (not shown) to be mounted later. In addition, although not shown in FIG. 1, when the first outer layer circuit pattern 120 is electrically connected to the external configuring unit, the first protecting layer 181 may be formed to expose the corresponding portion.

In addition, according to an exemplary embodiment of the present disclosure, the second protecting layer 182 may be formed below the second insulating layer 160 and the second outer layer circuit pattern 170. The second protecting layer 182 is formed to protect the second outer layer circuit pattern 170 from the outside. In this case, the second protecting layer 182 is formed to expose a portion electrically connected to the external configuring unit among the second outer layer circuit pattern 170. The first protecting layer 181 and the second protecting layer 182 according to an exemplary embodiment of the present disclosure may be made of a solder resist.

FIGS. 2 through 12 are illustrative views showing a method of manufacturing a package board according to the first exemplary embodiment of the present disclosure.

Referring to FIG. 2, the upper electrode 111 is formed on a carrier substrate 500.

According to an exemplary embodiment of the present disclosure, the carrier substrate 500 is to support the insulating layers, the circuit layers, and the like of the package board when forming the insulating layers, the circuit layers, and the like of the package board. Although FIG. 2 shows a case in which the carrier substrate 500 has a single layer and is made of a single material, the present disclosure is not limited thereto. For example, the carrier substrate 500 may have a copper clad laminate structure in which metal layers are formed both surfaces of the insulating layer. As such, the carrier substrate 500 may be any substrate of substrates for supporting and separating used in a field of circuit board.

According to an exemplary embodiment of the present disclosure, the upper electrode 111 is formed on a whole surface of the carrier substrate 500. In addition, when the upper electrode 111 is formed, if necessary, the first outer layer circuit pattern 120 may be simultaneously formed.

The upper electrode 111 and the first outer layer circuit pattern 120 according to an exemplary embodiment of the present disclosure may be formed by forming the metal layer on the carrier substrate 500 and then patterning the metal layer. Alternatively, the upper electrode 111 and the first outer layer circuit pattern 120 may be formed by forming a plating resist on the carrier substrate 500 and then performing the plating.

In the case in which the upper electrode 111 and the first outer layer circuit pattern 120 are formed on the carrier substrate 500, the upper electrode 111 is formed on the whole surface of the carrier substrate 500 and is formed to be spaced apart from side surfaces of the first outer layer circuit pattern 120.

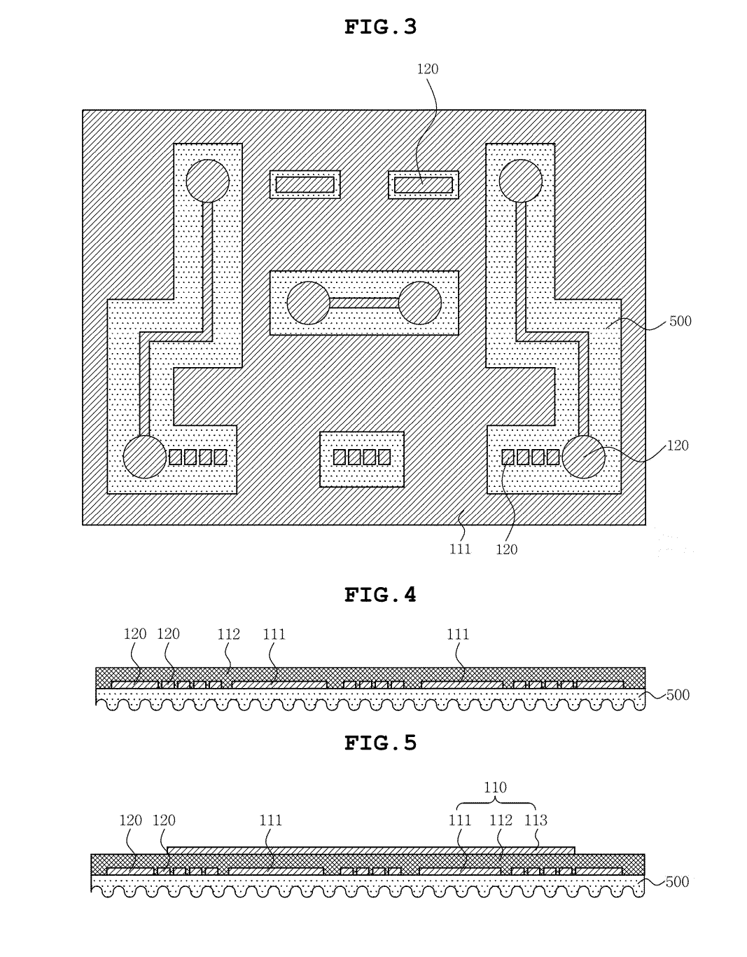

FIG. 3 is a plan view of FIG. 2.

Referring to FIG. 3, the first outer layer circuit pattern 120 is formed on the carrier substrate 500. In addition, the upper electrode 111 according to an exemplary embodiment of the present disclosure is formed on a region in which the first outer layer circuit pattern 120 is not formed on the carrier substrate 500, and is formed so as to be spaced apart from the first outer layer circuit pattern 120 as shown in FIG. 3. Therefore, the upper electrode 111 according to an exemplary embodiment of the present disclosure is formed to have a maximum area as possible.

Referring to FIG. 4, the dielectric layer 112 is formed on the carrier substrate 500.

According to an exemplary embodiment of the present disclosure, the dielectric layer 112 is formed to bury the upper electrode 111 and the first outer layer circuit pattern 120 formed on the carrier substrate 500.

According to an exemplary embodiment of the present disclosure, the dielectric layer 112 may be formed by applying a dielectric material in a liquid form or laminating the dielectric material in a film form on the carrier substrate 500. Here, the dielectric material may be any material of dielectric materials used in the capacitor field.

Referring to FIG. 5, the lower electrode 113 is formed on the dielectric layer 112.

According to an exemplary embodiment of the present disclosure, the lower electrode 113 is formed on a whole surface of the upper surface of the dielectric layer 112. In this case, the lower electrode 113 is formed on a region except for a region in which the via is to be formed later among the whole surface of the upper surface of the dielectric layer 112.

According to an exemplary embodiment of the present disclosure, the lower electrode 113 may be formed by forming the metal layer on the dielectric layer 112 and then patterning the metal layer. Alternatively, the lower electrode 113 may be formed by forming the plating resist on the dielectric layer 112 and then performing the plating.

According to an exemplary embodiment of the present disclosure, the upper electrode 111 and the lower electrode 113 are made of a conductive material used in a field of circuit board such as copper.

As such, the capacitor 110 according to an exemplary embodiment of the present disclosure is formed through processes of FIGS. 2 through 5 in which the upper electrode 111, the dielectric layer 112, and the lower electrode 113 are formed. Since the capacitor 110 according to an exemplary embodiment of the present disclosure is formed on the whole surface of the package board, the noise blocking function may be improved due to an increase in capacitance of the capacitor 110 and reliability of the signal transmission may be improved.

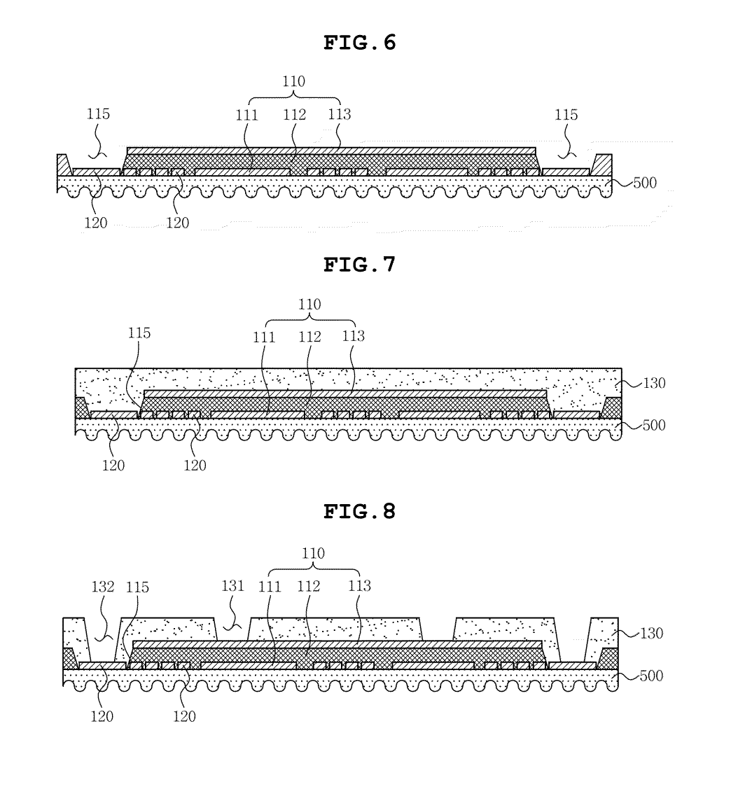

Referring to FIG. 6, opening parts 115 are formed in the dielectric layer 112.

According to an exemplary embodiment of the present disclosure, the opening part 115 may be formed by using a laser drill or an exposure and development method to the dielectric layer 112. The opening part 115 according to an exemplary embodiment of the present disclosure is formed to penetrate through the dielectric layer 112 and to expose a portion of the first outer layer circuit pattern 120. In addition, the opening part 115 is formed in a region in which a second via (not shown) is to be formed later. In this case, according to an exemplary embodiment of the present disclosure, in order to insulate between the lower electrode 113 and the second via (not shown) to be formed later, the opening part 115 is formed to have a diameter larger than that of the second via (not shown).

Referring to FIG. 7, the first insulating layer 130 is formed.

According to an exemplary embodiment of the present disclosure, the first insulating layer 130 is formed on the dielectric layer 112 and the lower electrode 113.

Therefore, the first insulating layer 130 is formed to bury the lower electrode 113. In addition, the first insulating layer 130 is formed in the opening part 115 of the dielectric layer 112 to thereby bury the first outer layer circuit pattern 120 exposed by the opening part 115. Therefore, the first insulating layer 130 is formed in a structure in which it is formed on the dielectric layer 112 and the lower electrode 113 and a portion thereof penetrates through the dielectric layer 112.

According to an exemplary embodiment of the present disclosure, the first insulating layer is made of a complex polymer resin typically used as an interlayer insulating material. For example, the first insulating layer 130 may be made of a prepreg, Ajinomoto Build up Film (ABF), and an epoxy based resin such as FR-4, Bismaleimide Triazine (BT), or the like. However, in an exemplary embodiment of the present disclosure, a material of forming the first insulating layers 130 is not limited thereto. The first insulating layer 130 may be selected from insulating materials known in the field of circuit board.

In addition, the first insulating layer 130 according to an exemplary embodiment of the present disclosure may be formed by applying a dielectric material in a liquid form or laminating the dielectric material in a film form on the dielectric layer 112 and the lower electrode 113.

Referring to FIG. 8, a first via hole 131 and a second via hole 132 are formed in the first insulating layer 130.

According to an exemplary embodiment of the present disclosure, the first via hole 131 exposing the lower electrode 113 by penetrating through the first insulating layer 130 and the second via hole 132 exposing the first outer layer circuit pattern 120 by penetrating through the first insulating layer 130 are formed. According to an exemplary embodiment of the present disclosure, the second via hole 132 is formed in the opening part 115.

For example, the first via hole 131 and the second via hole 132 may be formed by using a laser drill. Alternatively, the first via hole 131 and the second via hole 132 may be formed by using an exposure and development method. A method of forming the first via hole 131 and the second via hole 132 may be changed depending on the material of the first insulating layer 130 and a selection of those skilled in the art.

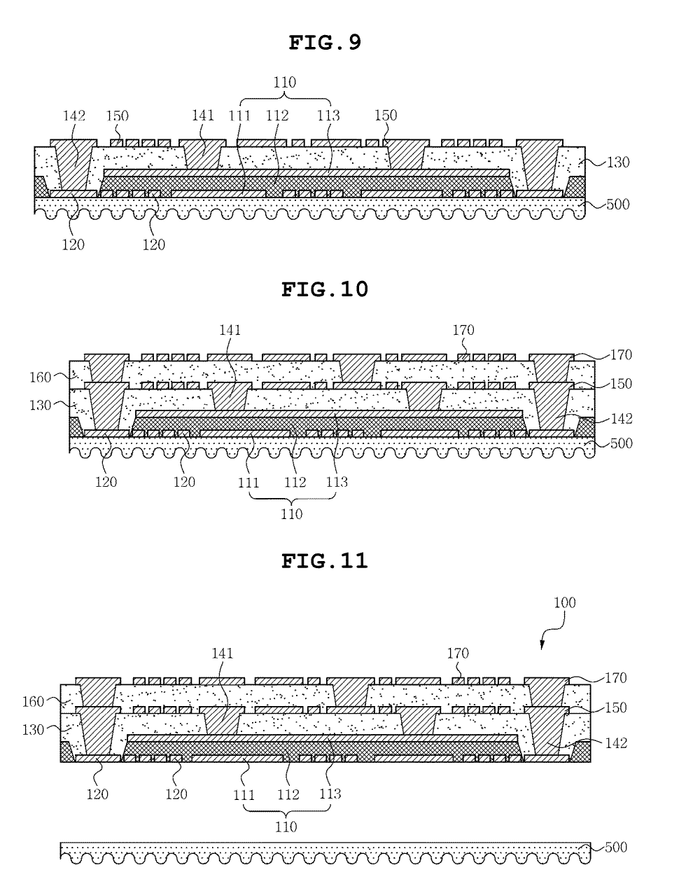

Referring to FIG. 9, the first via 141, the second via 142, and the inner layer circuit pattern 150 are formed.

According to an exemplary embodiment of the present disclosure, the first via 141 and the second via 142 are formed in the first via hole 131 and the second via hole 132. In addition, the inner layer circuit pattern 150 is formed on the first insulating layer 130 and is formed so that a portion thereof is bonded to the first via 141 and the second via 142.

The first via 141, the second via 142, and the inner layer circuit pattern 150 according to an exemplary embodiment of the present disclosure may be formed by any method of methods of forming the via and circuit pattern used in a field of circuit board. In addition, the first via 141, the second via 142, and the inner layer circuit pattern 150 may be simultaneously or separately formed by using the method of forming the via and the circuit pattern used in a field of circuit board. That is, the first via 141 and the inner layer circuit pattern 150 may be simultaneously formed or after the first via 141 is formed, the inner layer circuit pattern 150 may be formed.

The first via 141, the second via 142, and the inner layer circuit pattern 150 according to an exemplary embodiment of the present disclosure may be made of a conductive material used in a field of circuit board such as copper.

The first via 141 formed as described above is formed in the first insulating layer 130 to thereby electrically connect the inner layer circuit pattern 150 and the lower electrode 113 to each other. In addition, the second via 142 is formed in the first insulating layer 130 penetrating through the dielectric layer 112 to thereby electrically connect the inner layer circuit pattern 150 and the first outer layer circuit pattern 120 to each other.

Referring to FIG. 10, the second insulating layer 160 and the second outer layer circuit pattern 170 are formed.

According to an exemplary embodiment of the present disclosure, the second insulating layer 160 is formed on the first insulating layer 130 to thereby bury the inner layer circuit pattern 150. In addition, according to an exemplary embodiment of the present disclosure, the second outer layer circuit pattern 170 is formed on the second insulating layer 160. Here, the second outer layer circuit pattern 170 is formed to have a structure protruded from the upper surface of the second insulating layer 160.

Since the second insulating layer 160 and the second outer layer circuit pattern 170 according to an exemplary embodiment of the present disclosure may be formed by using the method of forming the first insulating layer 130 and the inner layer circuit pattern 150, a detailed description thereof will be omitted.

In addition, according to an exemplary embodiment of the present disclosure, a via electrically connecting the inner layer circuit pattern 150 and the second outer layer circuit pattern 170 may be further formed in the second insulating layer 160. The via formed in this case may also be formed by using the same method as the first via 141.

Referring to FIG. 11, the carrier substrate 500 is removed.

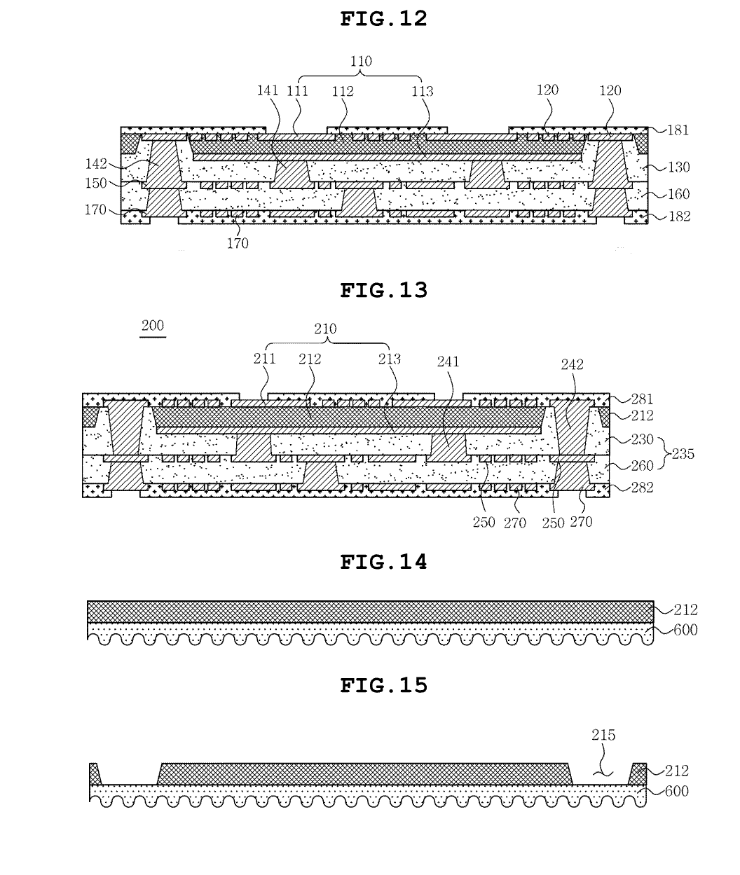

Referring to FIG. 12, the first protecting layer 181 and the second protecting layer 182 are formed.

The package board 100 shown in FIG. 12 shows the package board 100 of

FIG. 11 that top and bottom are reversed for convenience of explanation. Hereinafter, upper and lower directions will be described based on the described corresponding drawing.

According to an exemplary embodiment of the present disclosure, the first protecting layer 181 is formed on the dielectric layer 112 and the upper electrode 111. In addition, the first protecting layer 181 is formed to expose a potion of the upper electrode 111. In this case, the upper electrode 111 exposed by the first protecting layer 181 is a region electrically connected to electronic components (not shown) to be mounted later.

In addition, according to an exemplary embodiment of the present disclosure, the second protecting layer 182 is formed below the second insulating layer 160 and is formed to protect the second outer layer circuit pattern 170. In this case, the second protecting layer 182 is formed to expose a portion electrically connected to the external configuring unit among the second outer layer circuit pattern 170.

According to an exemplary embodiment of the present disclosure, the first protecting layer 181 and the second protecting layer 182 may be made of a solder resist.

The package board 100 of FIG. 1 may be formed by the method of FIGS. 2 through 12 as described above.

### Second Exemplary Embodiment

FIG. 13 is an illustrative view showing a package board according to a second exemplary embodiment of the present disclosure.

Referring to FIG. 13, the package board 200 according to a second exemplary embodiment of the present disclosure includes an insulating layer 235, an inner layer circuit pattern 250, and a capacitor 210. In addition, the package board 200 may further include a first outer layer circuit pattern 220, a second outer layer circuit pattern 270, a first via 241, a second via 242, a first protecting layer 281, and a second protecting layer 282.

The insulating layer 235 according to an exemplary embodiment of the present disclosure may be classified into a first insulating layer 230 and a second insulating layer 260 formed below the first insulating layer 230. Although an exemplary embodiment of the present disclosure describes the insulating layer having a two-layer structure, this is only an illustration, and the number of layers of the insulating layer 235 may be changed according to a selection of those skilled in the art.

According to an exemplary embodiment of the present disclosure, the first insulating layer 230 and the second insulating layer 260 may be made of a complex polymer resin typically used as an interlayer insulating material.

In addition, according to an exemplary embodiment of the present disclosure, a portion of the first insulating layer 230 may be formed so as to penetrate through a dielectric layer 212.

According to an exemplary embodiment of the present disclosure, the capacitor 210 includes the dielectric layer 212, a lower electrode 213, and an upper electrode 211.

According to an exemplary embodiment of the present disclosure, the dielectric layer 212 is formed on the first insulating layer 230. The dielectric layer 212 may be made of any material of dielectric materials used in a capacitor field.

In addition, according to an exemplary embodiment of the present disclosure, the lower electrode 213 is formed on a whole surface of an upper surface of the first insulating layer 230 and is formed to be buried in the first insulating layer 230.

In addition, according to an exemplary embodiment of the present disclosure, the upper electrode 211 is formed on a whole surface of an upper surface of the dielectric layer 212 and is formed to be protruded from the upper surface of the dielectric layer 212 to the outside.

The lower electrode 213 and the upper electrode 211 according to an exemplary embodiment of the present disclosure may be made of any material used as an electrode in a capacitor field.

According to an exemplary embodiment of the present disclosure, the inner layer circuit pattern 250 may be formed on the second insulating layer 260 to be buried in the first insulating layer 230. In addition, the inner layer circuit pattern 250 is made of a conductive material used in a field of circuit board such as copper. Although an exemplary embodiment of the present disclosure describes a case in which the inner layer circuit pattern 250 is formed in a single layer on the first insulating layer 230 by way of example, a position at which the inner layer circuit pattern 250 is formed and the number of layers of the inner layer circuit pattern 250 may be changed according to a selection of those skilled in the art.

According to an exemplary embodiment of the present disclosure, the first via 241 penetrates through the first insulating layer 230 to thereby electrically connect the inner layer circuit pattern 250 and the lower electrode 213 of the capacitor 210 to each other.

In addition, according to an exemplary embodiment of the present disclosure, the second via 242 is formed in the first insulating layer 230 penetrating through the dielectric layer 212 to thereby electrically connect the inner layer circuit pattern 250 and the first outer layer circuit pattern 220 to each other. The first via 241 and the second via 242 according to an exemplary embodiment of the present disclosure are made of a conductive material used in the field of circuit board.

According to an exemplary embodiment of the present disclosure, the first outer layer circuit pattern 220 may be formed on the upper surface of the dielectric layer 212 and the second outer layer circuit pattern 270 may be formed on the lower surface of the second insulting layer 260.

The first outer layer circuit pattern 220 according to an exemplary embodiment of the present disclosure may be formed to be protruded from the upper surface of the dielectric layer 212 and the second outer layer circuit pattern 270 may be formed to be protruded from the lower surface of the second insulating layer 260. However, the entire first outer layer circuit pattern 220 is not formed on the dielectric layer 212. As shown in FIG. 13, the first outer layer circuit pattern 220 connected to the second via 242 may be formed on the upper surface of the first insulating layer 230 penetrating through the dielectric layer 212. The first outer layer circuit pattern 220 and the second outer layer circuit pattern 270 according to an exemplary embodiment of the present disclosure are made of a conductive material used in the field of circuit board.

According to an exemplary embodiment of the present disclosure, the first protecting layer 281 may be formed on the dielectric layer 212, the upper electrode 211, and the first outer layer circuit pattern 220. According to an exemplary embodiment of the present disclosure, the first protecting layer 281 is formed to expose a region connected to electronic components (not shown) to be mounted later among the upper electrode 211.

In addition, according to an exemplary embodiment of the present disclosure, the second protecting layer 282 may be formed below the second insulating layer 260 and the second outer layer circuit pattern 270. According to an exemplary embodiment of the present disclosure, the second protecting layer 282 is formed to expose a portion electrically connected to the external configuring unit among the second outer layer circuit pattern 270. The first protecting layer 281 and the second protecting layer 282 according to an exemplary embodiment of the present disclosure may be made of a solder resist.

As described above, the package board according to the second exemplary embodiment of the present disclosure has positions in which the upper electrode 211 and the first outer layer circuit pattern 220 are formed, different from the package board 200 according to the first exemplary embodiment of the present disclosure, but other configuring units are similar to each other. Therefore, other detailed descriptions except for the positions in which the upper electrode 211 and the first outer layer circuit pattern 220 are formed make reference to the description of FIG. 1.

FIGS. 14 through 22 are illustrative views showing a method of manufacturing a package board 200 according to the second exemplary embodiment of the present disclosure.

Referring to FIG. 14, the dielectric layer 212 is formed on a carrier substrate 600.

According to an exemplary embodiment of the present disclosure, the dielectric layer 212 may be formed by applying a dielectric material in a liquid form or laminating the dielectric material in a film form on the carrier substrate 600. Here, the dielectric material may be any material of dielectric materials used in the capacitor field.

Referring to FIG. 15, opening parts 215 are formed in the dielectric layer 212.

According to an exemplary embodiment of the present disclosure, the opening part 215 may be formed by using a laser drill or an exposure and development method to the dielectric layer 212. The opening part 215 according to an exemplary embodiment of the present disclosure is formed to penetrate through the dielectric layer 212 in which a second via (not shown) is to be formed later and to expose a portion of the carrier substrate 600. In this case, according to an exemplary embodiment of the present disclosure, in order to insulate between the lower electrode 213 and the second via (not shown) to be formed later, the opening part 215 is formed to have a diameter larger than that of the second via (not shown).

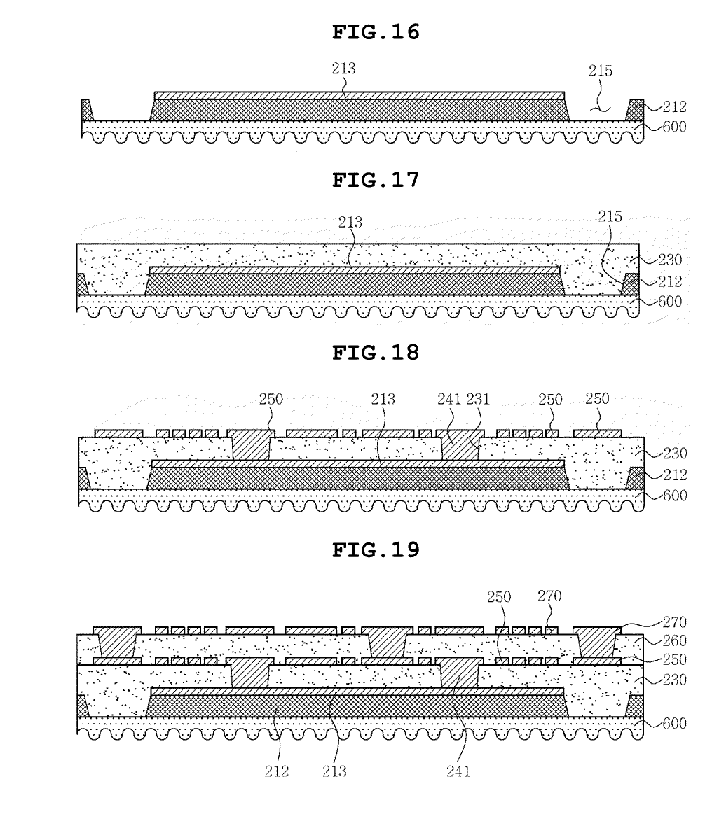

Referring to FIG. 16, the lower electrode 213 is formed on the dielectric layer 212.

A method of forming the lower electrode 213 according to an exemplary embodiment of the present disclosure makes reference to FIG. 5.

Referring to FIG. 17, the first insulating layer 230 is formed.

According to an exemplary embodiment of the present disclosure, the first insulating layer 230 is formed on the dielectric layer 212 and the lower electrode 213 and is formed to bury the lower electrode 213. In this case, an inner portion of the opening part 215 of the dielectric layer 212 is buried by the first insulating layer 230. Therefore, the first insulating layer 230 is formed in a structure in which it is formed on the dielectric layer 212 and the lower electrode 213 and a portion thereof penetrates through the dielectric layer 212.

According to an exemplary embodiment of the present disclosure, the first insulating layer 230 is made of a complex polymer resin typically used as an interlayer insulating material.

In addition, the first insulating layer 230 according to an exemplary embodiment of the present disclosure may be formed by applying a dielectric material in a liquid form or laminating the dielectric material in a film form on the dielectric layer 212 and the lower electrode 213.

Referring to FIG. 18, the first via 241 and the inner layer circuit pattern 250 are formed in the first insulating layer 230.

According to an exemplary embodiment of the present disclosure, a first via hole 231 is first formed in the first insulating layer 230. The first via hole 231 according to an exemplary embodiment of the present disclosure is formed to penetrate through the first insulating layer 230 to thereby expose the lower electrode 213. For example, the first via hole 231 may be formed by using a laser drill or an exposure and development method. A method of forming the first via hole 231 may be changed depending on the material of the first insulating layer 230 and a selection of those skilled in the art.

In addition, according to an exemplary embodiment of the present disclosure, the first via 241 is formed in the first via hole 231 and the inner layer circuit pattern 250 is formed on the first insulating layer 230. In addition, the inner layer circuit pattern 250 may be formed so that a portion thereof is bonded to the first via 241.

A detailed description of forming the first via 241 and the inner layer circuit pattern 250 according to an exemplary embodiment of the present disclosure makes reference to the method of forming the first via 241 and the inner layer circuit pattern 250 of FIG. 9.

Referring to FIG. 19, the second insulating layer 260 and the second outer layer circuit pattern 270 are formed.

A detailed description of forming the second insulating layer 260 and the second outer layer circuit pattern 270 according to an exemplary embodiment of the present disclosure makes reference to FIG. 10.

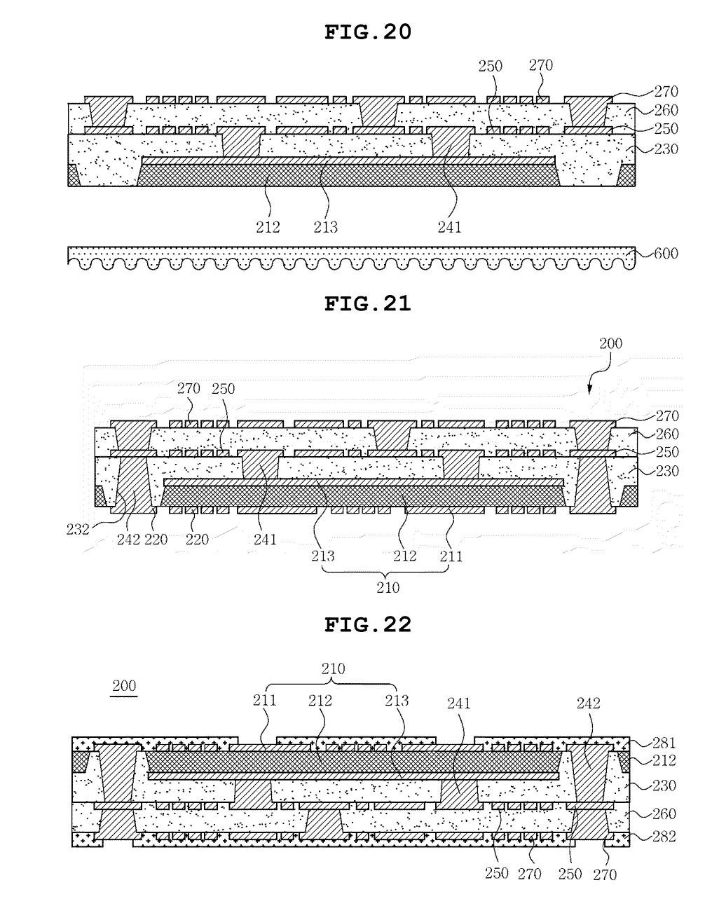

Referring to FIG. 20, the carrier substrate 600 is removed.

Referring to FIG. 21, the upper electrode 211, the second via 242, and the first outer layer circuit pattern 220 are formed.

According to an exemplary embodiment of the present disclosure, the second via hole 232 is first formed.

The second via hole 232 according to an exemplary embodiment of the present disclosure is formed in the first insulating layer 230 formed to penetrate through the dielectric layer 212. The second via hole 232 is formed to expose a lower surface of the inner layer circuit pattern 250 by penetrating through the first insulating layer 230 penetrating through the dielectric layer 212.

The second via hole 232 according to an exemplary embodiment of the present disclosure may be formed by using a laser drill or an exposure and development method. In addition, a method of forming the second via hole 232 may be changed depending on the material of the first insulating layer 230 and a selection of those skilled in the art.

In addition, according to an exemplary embodiment of the present disclosure, the second via 242 is formed in the second via hole 232 and the upper electrode 211 and the first outer layer circuit pattern 220 are formed below the dielectric layer 212.

The upper electrode 211, the second via 242, and the first outer layer circuit pattern 220 according to an exemplary embodiment of the present disclosure may be formed by any method of known methods of forming the via and circuit pattern. In addition, the upper electrode 211, the second via 242, and the first outer layer circuit pattern 220 may be made of a conductive material. According to an exemplary embodiment of the present disclosure, the upper electrode 211 is formed, such that the capacitor 210 having the upper electrode 211, the lower electrode 213, and the dielectric layer 212 is formed.

In the case in which the upper electrode 211 and the first outer layer circuit pattern 220 are formed on the dielectric layer 212 according to an exemplary embodiment of the present disclosure, the upper electrode 211 is formed on a whole surface of the dielectric layer 212 and is formed to be spaced apart from side surfaces of the first outer layer circuit pattern 220. In addition, a portion of the first outer layer circuit pattern 220 may be bonded to the second via 242. That is, the second via 242 may penetrate through the first insulating layer 230 to electrically connect the inner layer circuit pattern 250 and the first outer layer circuit pattern 220 to each other.

Referring to FIG. 22, the first protecting layer 281 and the second protecting layer 282 are formed.

The package board 200 shown in FIG. 22 shows the package board 200 of FIG. 21 that top and bottom are reversed.

A method of forming the first protecting layer 281 and the second protecting layer 282 according to an exemplary embodiment of the present disclosure makes reference to FIG. 12.

The package board 200 of FIG. 13 may be formed by the method of

FIGS. 14 through 22 as described above.

### Third Exemplary Embodiment

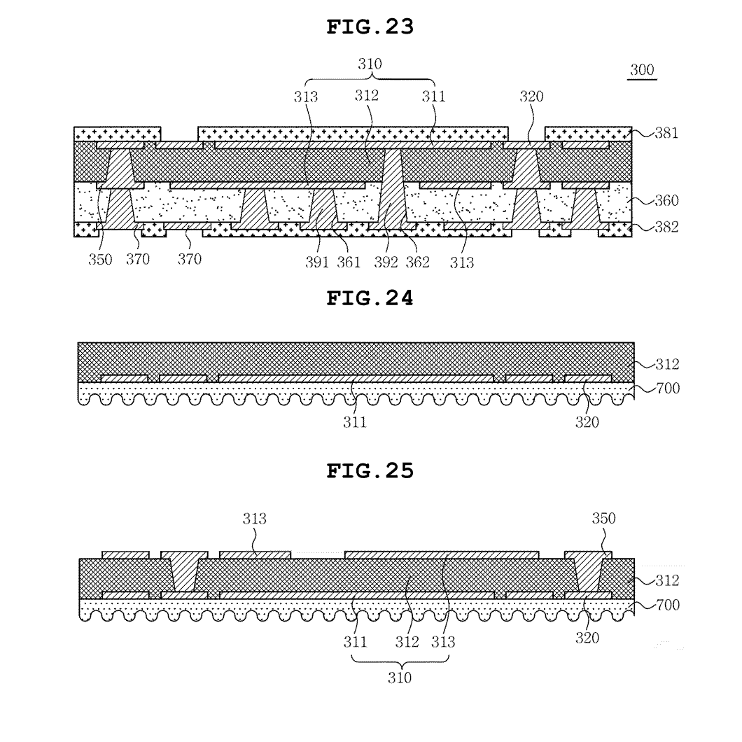

FIG. 23 is an illustrative view showing a package board according to a third exemplary embodiment of the present disclosure.

Referring to FIG. 23, the package board 300 according to a third exemplary embodiment of the present disclosure includes an insulating layer 360, a capacitor 310, a third via 391, and a fourth via 392. In addition, the package board 300 may further include an inner layer circuit pattern 350, a first outer layer circuit pattern 320, a second outer layer circuit pattern 370, a first protecting layer 381, and a second protecting layer 382.

The insulating layer 360 according to an exemplary embodiment of the present disclosure may be made of a complex polymer resin typically used as an interlayer insulating material. For example, the insulating layer 360 may be made of a prepreg, Ajinomoto Build up Film (ABF), and an epoxy based resin such as FR-4, Bismaleimide Triazine (BT), or the like. However, in an exemplary embodiment of the present disclosure, a material of forming the insulating layer 360 is not limited thereto. The insulating layer 360 may be selected from insulating materials known in the field of circuit board.

According to an exemplary embodiment of the present disclosure, the capacitor 310 includes a dielectric layer 312, a lower electrode 313, and an upper electrode 311. In addition, the capacitor 310 has a structure in which the dielectric layer 312 is interposed between the upper electrode 311 and the lower electrode 313.

According to an exemplary embodiment of the present disclosure, the dielectric layer 312 is formed on the insulating layer 360. The dielectric layer 312 may be made of any material of dielectric materials used in a capacitor field.

In addition, according to an exemplary embodiment of the present disclosure, the lower electrode 313 is formed on a whole surface of an upper surface of the insulating layer 360 and is formed to be buried in the insulating layer 360. That is, the lower electrode 313 is formed so that side surfaces and a lower surface thereof are positioned in the insulating layer 360 and an upper surface thereof is exposed to the outside of the insulating layer 360.

In addition, according to an exemplary embodiment of the present disclosure, the upper electrode 311 is formed on a whole surface of an upper surface of the dielectric layer 312 and is formed to be buried in the dielectric layer 312. That is, the upper electrode 311 is formed so that side surfaces and a lower surface thereof is positioned in the dielectric layer 312 and an upper surface thereof is exposed to the outside of the dielectric layer 312.

The lower electrode 313 and the upper electrode 311 according to an exemplary embodiment of the present disclosure are made of a conductive material.

For example, the lower electrode 313 and the upper electrode 311 may be made of copper (Cu). However, a material of the lower electrode 313 and the upper electrode 311 is not limited to copper and any material may be used as long as it is used as an electrode in the capacitor field.

As such, according to an exemplary embodiment of the present disclosure, since the capacitor 310 is formed on the outermost layer of the package board 300 to thereby decrease a signal transmission distance with electronic components (not shown) to be mounted later, a signal transmission speed may be improved. In addition, since the capacitor 310 is formed on the whole surface of the package board 300, the noise blocking function may be improved due to an increase in capacitance of the capacitor 310 and reliability of the signal transmission may be improved. In addition, since the capacitor 310 is formed on the whole surface of the package board 300, an occurrence of warpage of the package board 300 may be decreased.

According to an exemplary embodiment of the present disclosure, the inner layer circuit pattern 350 may be formed in the insulating layer 360. The inner layer circuit pattern 350 according to an exemplary embodiment of the present disclosure may be formed on the upper surface of the insulating layer 360 and may be formed to be buried in the insulating layer 360. The inner layer circuit pattern 350 formed as described above may be formed on the same layer as the lower electrode 313 and may be formed so that side surfaces thereof are spaced apart from the lower electrode 313. That is, in the case in which the inner layer circuit pattern is formed, the lower electrode 313 may be formed on the whole surface of the insulating layer 360 except for a region in which the inner layer circuit pattern 350 is formed. The inner layer circuit pattern 350 according to an exemplary embodiment of the present disclosure is made of a conductive material used in a field of circuit board. For example, the inner layer circuit pattern 350 may be made of copper.

According to an exemplary embodiment of the present disclosure, the first outer layer circuit pattern 320 may be formed on the upper surface of the dielectric layer 312. In this case, the first outer layer circuit pattern 320 may be formed to be buried in the dielectric layer 312 and have side surfaces formed to be spaced apart from the upper electrode 311, similar to the upper electrode 311. As the first outer layer circuit pattern 320 is formed, the upper electrode 311 of the capacitor 310 may be formed on a region in which the first outer layer circuit pattern 320 is not formed among the upper surface of the dielectric layer 312.

In addition, according to an exemplary embodiment of the present disclosure, the second outer layer circuit pattern 370 may be formed on the lower surface of the insulating layer 360. In this case, the second outer layer circuit pattern 370 may be formed in a structure protruded from the lower surface of the insulating layer 360. In addition, the second outer layer circuit pattern 370 may include an external connecting pad electrically connected to an external configuring unit.

The first outer layer circuit pattern 320 and the second outer layer circuit pattern 370 according to an exemplary embodiment of the present disclosure may be made of a conductive material used in the field of circuit board such as copper.

According to an exemplary embodiment of the present disclosure, the third via 391 electrically connecting the second outer layer circuit pattern 370 and the lower electrode 313 may be formed. For example, the third via 391 is formed to penetrate through the insulating layer 360, such that an upper portion thereof may be bonded to the lower electrode 313 and a lower portion thereof may be bonded to the second outer layer circuit pattern 370.

In addition, according to an exemplary embodiment of the present disclosure, the fourth via 392 electrically connecting the second outer layer circuit pattern 370 and the upper electrode 311 may be formed. For example, the fourth via 392 is formed to penetrate through the insulating layer 360 and the dielectric layer 312, such that an upper portion thereof may be bonded to the upper electrode 311 and a lower portion thereof may be bonded to the second outer layer circuit pattern 370. In this case, in order to insulate between the fourth via 392 and the lower electrode 313, side surfaces of the fourth via 392 are formed to be spaced apart from the lower electrode 313.

The third via and the fourth via 392 according to an exemplary embodiment of the present disclosure may be made of a conductive material used in a field of circuit board such as copper.

In addition, although not described in detail in an exemplary embodiment of the present disclosure, a via formed in the insulating layer 360 or the dielectric layer 312 and electrically connecting the respective layers may be further formed. In addition, although not shown, the inner layer circuit pattern having a plurality of layers may be further formed in the package board 300. In this case, it is apparent that vias electrically connecting the respective layers to each other may be further formed.

According to an exemplary embodiment of the present disclosure, the first protecting layer 381 may be formed on the dielectric layer 312, the upper electrode 311, and the first outer layer circuit pattern 320. The first protecting layer 381 is formed to protect the upper electrode 311 and the first outer layer circuit pattern 320 from the outside. In this case, the first protecting layer 381 is formed to expose a potion of the first outer layer circuit pattern 320. Here, the first outer layer circuit pattern 320 exposed by the first protecting layer 381 is a portion electrically connected to the external configuring unit such as electronic components (not shown) to be mounted later.

In addition, according to an exemplary embodiment of the present disclosure, the second protecting layer 382 may be formed below the insulating layer 360 and the second outer layer circuit pattern 370. The second protecting layer 382 is formed to protect the second outer layer circuit pattern 370 from the outside. In this case, the second protecting layer 382 is formed to expose a portion electrically connected to the external configuring unit among the second outer layer circuit pattern 370.

The first protecting layer 381 and the second protecting layer 382 according to an exemplary embodiment of the present disclosure may be made of a solder resist.

FIGS. 24 through 30 are illustrative views showing a method of manufacturing a package board according to the third exemplary embodiment of the present disclosure.

Referring to FIG. 24, the upper electrode 311, the first outer layer circuit pattern 320, and the dielectric layer 312 are formed on a carrier substrate 700.

Since a method of forming the upper electrode 311, the first outer layer circuit pattern 320, and the dielectric layer 312 on the carrier substrate 700 is the same as that of FIGS. 2 through 4, it makes reference to the method of FIGS. 2 through 4.

Referring to FIG. 25, the lower electrode 313 is formed on the dielectric layer 312.

According to an exemplary embodiment of the present disclosure, the lower electrode 313 is formed on a whole surface of the upper surface of the dielectric layer 312. In this case, the lower electrode 313 is formed on a region except for a region in which the fourth via (not shown) is to be formed later among the whole surface of the upper surface of the dielectric layer 312.

In addition, when the lower electrode 313 is formed, if necessary, the inner layer circuit pattern 350 may be simultaneously formed.

For example, in the case in which the inner layer circuit pattern 350 is formed, the lower electrode 313 is formed on the entire region in which the inner layer circuit pattern 350 and the fourth via (not shown) are not formed and is formed so that side surfaces thereof are spaced apart from the inner layer circuit pattern 350 and the fourth via (not shown).

According to an exemplary embodiment of the present disclosure, the lower electrode 313 may be formed by forming the metal layer on the dielectric layer 312 and then patterning the metal layer. Alternatively, the lower electrode 313 may be formed by forming the plating resist on the dielectric layer 312 and then performing the plating.

According to an exemplary embodiment of the present disclosure, the upper electrode 311 and the lower electrode 313 are made of a conductive material used in a field of circuit board such as copper.

As such, the capacitor 310 according to an exemplary embodiment of the present disclosure is formed through processes of FIGS. 24 and 25 in which the upper electrode 311, the dielectric layer 312, and the lower electrode 313 are formed. Since the capacitor 310 according to an exemplary embodiment of the present disclosure is formed on the whole surface of the package board 300, the noise blocking function may be improved due to an increase in capacitance of the capacitor 310 and reliability of the signal transmission may be improved.

In addition, according to an exemplary embodiment of the present disclosure, when the lower electrode 313 and the inner layer circuit pattern 350 are formed, a via electrically connecting the inner layer circuit pattern 350 and the first outer layer circuit pattern 320 may be further formed, if necessary.

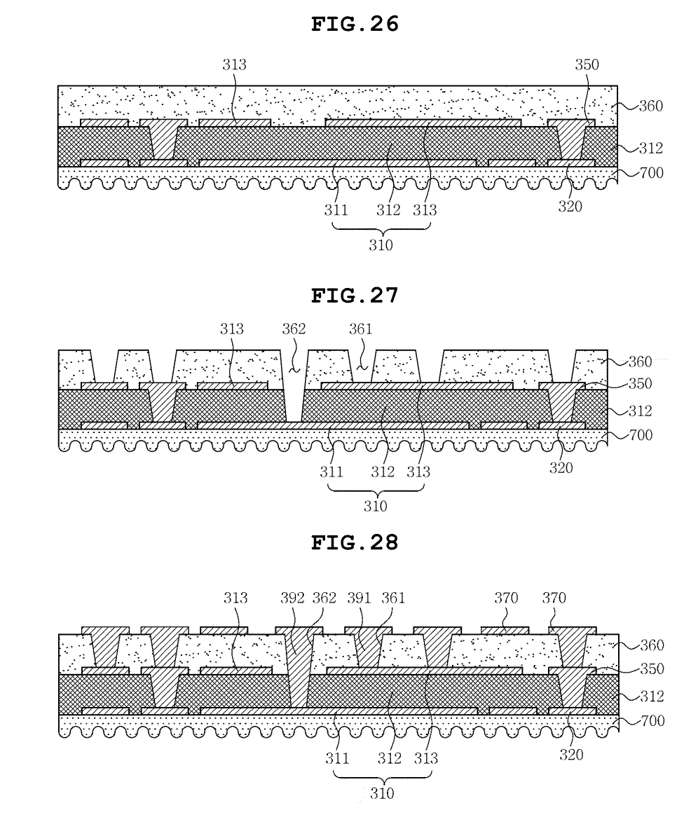

Referring to FIG. 26, the insulating layer 360 is formed.

According to an exemplary embodiment of the present disclosure, the insulating layer 360 is formed on the dielectric layer 312 and is formed to bury the lower electrode 313 and the inner layer circuit pattern 350.

According to an exemplary embodiment of the present disclosure, the insulating layer 360 may be made of a complex polymer resin typically used as an interlayer insulating material. For example, the insulating layer 360 may be made of a prepreg, Ajinomoto Build up Film (ABF), and an epoxy based resin such as FR-4,

Bismaleimide Triazine (BT), or the like. However, in an exemplary embodiment of the present disclosure, a material of forming the insulating layer 360 is not limited thereto. The insulating layer 360 may be selected from insulating materials known in the field of circuit board.

In addition, the insulating layer 360 according to an exemplary embodiment of the present disclosure may be formed by applying a dielectric material in a liquid form or laminating the dielectric material in a film form on the dielectric layer 312, the lower electrode 313, and the inner layer circuit pattern 350.

Referring to FIG. 27, a third via hole 361 and a fourth via hole 362 are formed in the insulating layer 360.

According to an exemplary embodiment of the present disclosure, the third via hole 361 is formed to penetrate through the insulating layer 360 to thereby expose the lower electrode 313. In addition, the fourth via hole 362 is formed to penetrate through the insulating layer 360 and the insulating layer 312 to thereby expose the upper electrode 311.

For example, the third via hole 361 and the fourth via hole 362 may be formed by using a laser drill. Alternatively, the third via hole 361 and the fourth via hole 362 may be formed by using an exposure and development method. A method of forming the third via hole 361 and the fourth via hole 362 may be changed depending on the material of the insulating layer 360 and a selection of those skilled in the art.

In addition, according to an exemplary embodiment of the present disclosure, the via hole penetrating through the insulating layer 360 to thereby expose the inner layer circuit pattern 350 may be further formed, if necessary.

Referring to FIG. 28, the third via 391, the fourth via 392, and the second outer layer circuit pattern 370 are formed.

According to an exemplary embodiment of the present disclosure, the third via 391 and the fourth via 392 are formed in the third via hole 361 and the fourth via hole 362. In addition, the second outer layer circuit pattern 370 is formed on the insulating layer 360 and is formed so that a portion of the second outer layer circuit pattern 370 is bonded to the third via 391 and the fourth via 392.

The third via 391, the fourth via 392, and the second outer layer circuit pattern 370 according to an exemplary embodiment of the present disclosure may be formed by any method of methods of forming the circuit pattern used in a field of circuit board. In addition, the third via 391, the fourth via 392, and the second outer layer circuit pattern 370 may be simultaneously or separately formed depending on which method is used to form the third via 391, the fourth via 392, and the second outer layer circuit pattern 370. In addition, the third via 391, the fourth via 392, and the second outer layer circuit pattern 370 according to an exemplary embodiment of the present disclosure may be made of a conductive material used in a field of circuit board such as copper.

The third via 391 formed as described above is formed in the insulating layer 360 to thereby electrically connect the second outer layer circuit pattern 370 and the lower electrode 313 to each other. In addition, the fourth via 392 is formed in the insulating layer 360 and the dielectric layer 312 to thereby electrically connect the second outer layer circuit pattern 370 and the upper electrode 311 to each other.

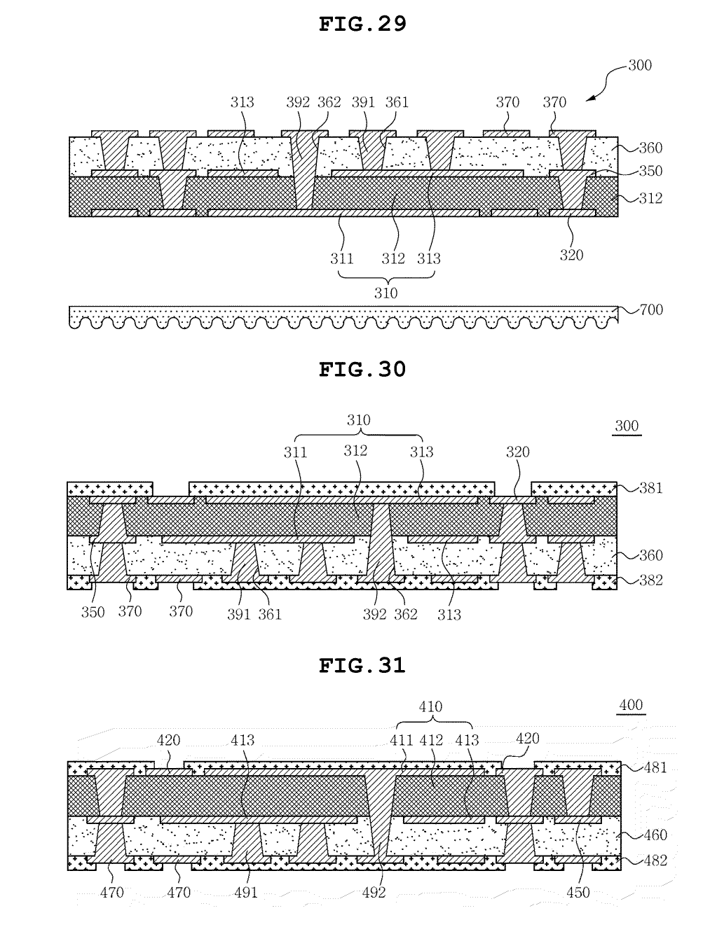

Referring to FIG. 29, the carrier substrate 700 is removed.

Referring to FIG. 30, the first protecting layer 381 and the second protecting layer 382 are formed.

The package board 300 shown in FIG. 30 shows the package board 300 of FIG. 29 that top and bottom are reversed for convenience of explanation.

Since the first protecting layer 381 and the second protecting layer 382 according to an exemplary embodiment of the present disclosure are the same as the first protecting layer 381 and the second protecting layer 382 of FIG. 12, a detailed description makes reference to FIG. 12.

### Fourth Exemplary Embodiment

FIG. 31 is an illustrative view showing a package board according to a fourth exemplary embodiment of the present disclosure.

Referring to FIG. 31, the package board 400 according to a fourth exemplary embodiment of the present disclosure includes an insulating layer 460, a capacitor 410, a third via 491, and a fourth via 492. In addition, the package board 400 may further include an inner layer circuit pattern 450, a first outer layer circuit pattern 420, a second outer layer circuit pattern 470, a first protecting layer 481, and a second protecting layer 482.

The insulating layer 460 according to an exemplary embodiment of the present disclosure may be made of a complex polymer resin typically used as an interlayer insulating material.

According to an exemplary embodiment of the present disclosure, the capacitor 410 includes a dielectric layer 412, a lower electrode 413, and an upper electrode 411.

According to an exemplary embodiment of the present disclosure, the dielectric layer 412 is formed on the insulating layer 460. The dielectric layer 412 may be made of any material of dielectric materials used in a capacitor field.

In addition, according to an exemplary embodiment of the present disclosure, the lower electrode 413 is formed on a whole surface of an upper surface of the insulating layer 460 and is formed to be buried in the insulating layer 460.

In addition, according to an exemplary embodiment of the present disclosure, the upper electrode 411 is formed on a whole surface of an upper surface of the dielectric layer 412 and is formed to be protruded from the upper surface of the dielectric layer 412 to the outside.

The lower electrode 413 and the upper electrode 411 according to an exemplary embodiment of the present disclosure are made of any material used as an electrode in a field of capacitor.

According to an exemplary embodiment of the present disclosure, the inner layer circuit pattern 450 may be formed on the insulating layer 460 and may be formed to be buried in the insulating layer 460. The inner layer circuit pattern 450 formed as described above may be formed on the same layer as the lower electrode 413 and may be formed so that side surfaces thereof are spaced apart from the lower electrode 413. That is, in the case in which the inner layer circuit pattern is formed, the lower electrode 413 may be formed on the whole surface of the insulating layer 460 except for a region in which the inner layer circuit pattern 450 is formed.

According to an exemplary embodiment of the present disclosure, the first outer layer circuit pattern 420 may be formed on an upper surface of the dielectric layer 412 and the second outer layer circuit pattern 470 may be formed on a lower surface of the insulating layer 460. In addition, the first outer layer circuit pattern 420 according to an exemplary embodiment of the present disclosure may be formed to be protruded from the upper surface of the dielectric layer 412 and the second outer layer circuit pattern 470 may be formed to be protruded from the lower surface of the insulating layer 460. The inner layer circuit pattern 450, the first outer layer circuit pattern 420, and the second outer layer circuit pattern 470 according to an exemplary embodiment of the present disclosure are made of a conductive material used in the field of circuit board.

According to an exemplary embodiment of the present disclosure, the third via 491 penetrates through the insulating layer 460 to thereby electrically connect the second outer layer circuit pattern 470 and the lower electrode 413 to each other.

In addition, according to an exemplary embodiment of the present disclosure, the fourth via 492 penetrates through the insulating layer 460 and the dielectric layer 412 to thereby electrically connect the second outer layer circuit pattern 470 and the upper electrode 411 to each other. The first via 441 and the second via 442 according to an exemplary embodiment of the present disclosure are made of a conductive material used in the field of circuit board.

According to an exemplary embodiment of the present disclosure, the first protecting layer 481 may be formed on the dielectric layer 412, the upper electrode 411, and the first outer layer circuit pattern 420. According to an exemplary embodiment of the present disclosure, the first protecting layer 481 is formed to expose a region connected to electronic components (not shown) to be mounted later among the upper electrode 411.

In addition, according to an exemplary embodiment of the present disclosure, the second protecting layer 482 may be formed below the insulating layer 460 and the second outer layer circuit pattern 470. According to an exemplary embodiment of the present disclosure, the second protecting layer 482 is formed to expose a portion electrically connected to the external configuring unit among the second outer layer circuit pattern 470. The first protecting layer 481 and the second protecting layer 482 according to an exemplary embodiment of the present disclosure may be made of a solder resist.

As described above, the package board 400 according to the second exemplary embodiment of the present disclosure has positions in which the upper electrode 411 and the first outer layer circuit pattern 420 are formed, different from the package board 300 according to the third exemplary embodiment of the present disclosure, but other configuring units are similar to each other. Therefore, other detailed descriptions except for the positions in which the upper electrode 411 and the first outer layer circuit pattern 420 are formed make reference to the description of FIG. 23.

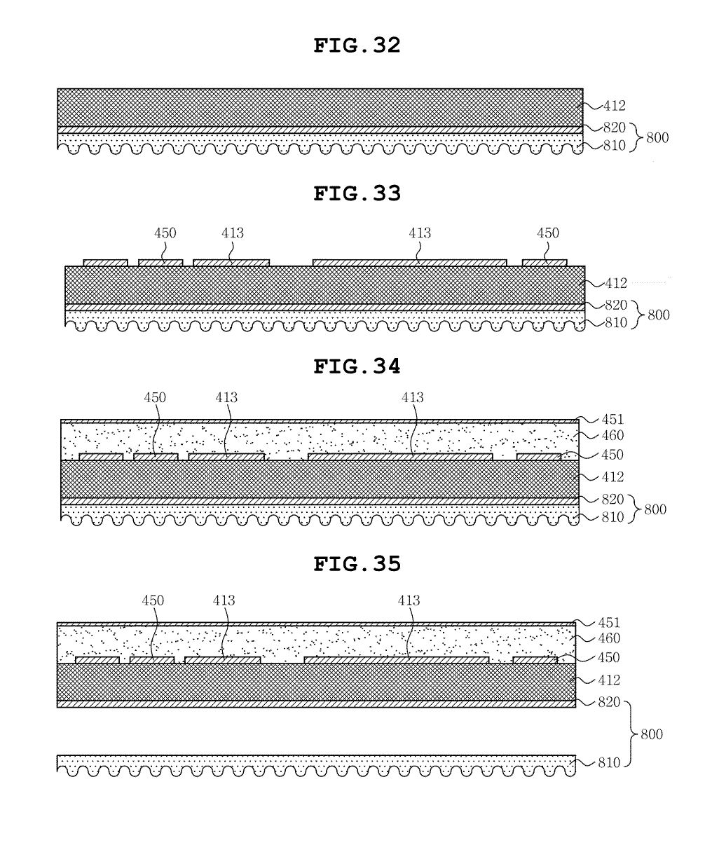

FIGS. 32 through 37 are illustrative views showing a method of manufacturing a package board according to the fourth exemplary embodiment of the present disclosure.

Referring to FIG. 32, the dielectric layer 412 is formed on a carrier substrate 800.

According to an exemplary embodiment of the present disclosure, the carrier substrate 800 may be formed in a structure in which a carrier metal layer 820 is laminated on a carrier core 810. Although FIG. 32 shows a case in which the carrier metal layer 820 is formed on one surface of the carrier core 810, the carrier metal layer 820 may be formed on both surfaces of the carrier substrate 800. In the case in which the carrier metal layer 820 is formed on both surfaces of the carrier substrate 800, a process of forming the package board on both surfaces of the carrier substrate 800 may be simultaneously formed.

According to an exemplary embodiment of the present disclosure, the dielectric layer 412 is formed on the carrier substrate 800. According to an exemplary embodiment of the present disclosure, the dielectric layer 412 may be formed by applying a dielectric material in a liquid form or laminating the dielectric material in a film form on the carrier substrate 800. Here, the dielectric material may be any material of dielectric materials used in the capacitor field.

Referring to FIG. 33, the lower electrode 413 is formed.

According to an exemplary embodiment of the present disclosure, the lower electrode 413 is formed on the dielectric layer 412. According to an exemplary embodiment of the present disclosure, the lower electrode 413 may be formed on a whole surface of the dielectric layer 412.

In addition, the inner layer circuit pattern 450 may be formed on the dielectric layer 412, if necessary. In this case, the lower electrode 413 may be formed on an upper surface of the dielectric layer 412 except for a region in which the inner layer circuit pattern 450 is formed. In addition, the lower electrode 413 may be formed so that the lower electrode 413 and side surfaces of the inner layer circuit pattern 450 are spaced apart from each other in order to implement insulation from the inner layer circuit pattern 450.

The lower electrode 413 and the inner layer circuit pattern 450 according to an exemplary embodiment of the present disclosure may be formed by a method of forming a circuit pattern known in the field of circuit board. For example, the lower electrode 413 and the inner layer circuit pattern 450 may be formed by forming the metal layer on the whole surface of the dielectric layer 412 and then performing the patterning. Alternatively, the lower electrode 413 and the inner layer circuit pattern 450 may be formed by forming a plating resist on the dielectric layer 412 and then performing the plating.

The lower electrode 413 and the inner layer circuit pattern 450 according to an exemplary embodiment of the present disclosure are made of a conductive material.

Referring to FIG. 34, the insulating layer 460 is formed.

According to an exemplary embodiment of the present disclosure, the insulating layer 460 is formed on the dielectric layer 412 and is formed to bury the lower electrode 413 and the inner layer circuit pattern 450.

According to an exemplary embodiment of the present disclosure, the insulating layer 460 may be made of a complex polymer resin typically used as an interlayer insulating material.

In addition, the insulating layer 460 according to an exemplary embodiment of the present disclosure may be formed by applying a dielectric material in a liquid form or laminating the dielectric material in a film form on the dielectric layer 412, the lower electrode 413, and the inner layer circuit pattern 450.

In addition, according to an exemplary embodiment of the present disclosure, a metal layer 451 may be further formed on the insulating layer 460. For example, the metal layer 451 may be formed on the insulating layer 460 by a plating method or may be formed by laminating and then pressing a separate metal layer 451 on the insulating layer 460. The metal layer 451 according to an exemplary embodiment of the present disclosure may be made of a conductive material used in a field of circuit board. The metal layer 451 according to an exemplary embodiment of the present disclosure may serve as a seed layer for performing an electroplating when a second outer layer circuit pattern (not shown) is formed. Alternatively, the metal layer 451 may be formed to improve flatness for forming a fine circuit pattern. However, the metal layer 451 is formed if necessary and is not necessarily formed. For example, a process of forming the metal layer 451 may be omitted or may be removed from a subsequent process.

Referring to FIG. 35, the carrier substrate 800 is removed.

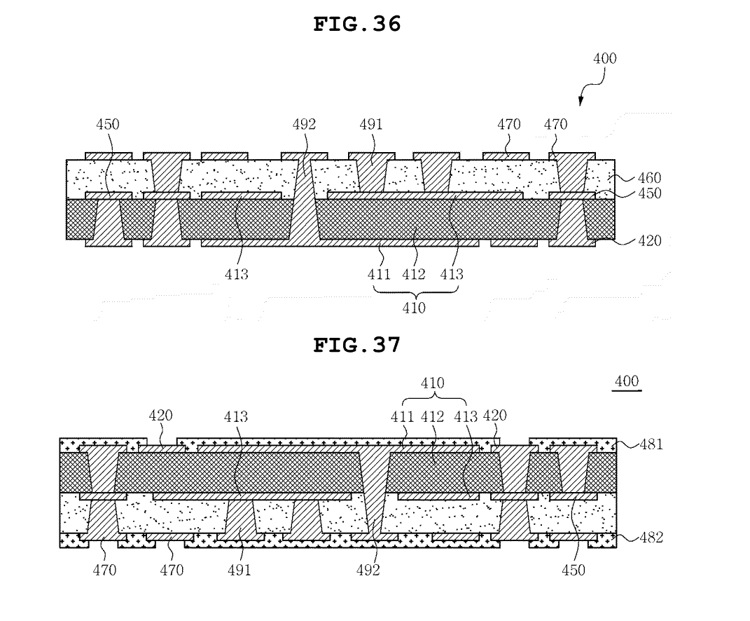

Referring to FIG. 36, the first outer layer circuit pattern 420, the second outer layer circuit pattern 470, the third via 491, and the fourth via 492 are formed.

According to an exemplary embodiment of the present disclosure, the first outer layer circuit pattern 420 is formed on a lower surface of the dielectric layer 412 and is formed to be protruded from the dielectric layer 412. In addition, the second outer layer circuit pattern 470 is formed on an upper surface of the insulating layer 460 and is formed to be protruded from the insulating layer 460.

The third via 491 according to an exemplary embodiment of the present disclosure penetrates through the insulating layer 460 and is formed so that an upper portion thereof is bonded to the second outer layer circuit pattern 470 and a lower portion thereof is bonded to the lower electrode 413. In addition, the fourth via 492 penetrates through the dielectric layer 412 and the insulating layer 460 and is formed so that an upper portion thereof is bonded to the second outer layer circuit pattern 470 and a lower portion thereof is bonded to the upper electrode 411.

The first outer layer circuit pattern 420, the second outer layer circuit pattern 470, the third via 491, and the fourth via 492 according to an exemplary embodiment of the present disclosure as described above may be formed by a method of forming a circuit pattern and a via known in the field of circuit board. In addition, the first outer layer circuit pattern 420, the second outer layer circuit pattern 470, the third via 491, and the fourth via 492 according to an exemplary embodiment of the present disclosure may be made of a conductive material used in a field of circuit board such as copper.

In addition, a via for electrically connecting between the first outer layer circuit pattern 420, the second outer layer circuit pattern 470, and the inner layer circuit pattern 450 may be further formed, if necessary.

Referring to FIG. 37, the first protecting layer 481 and the second protecting layer 482 are formed.

The package board 400 shown in FIG. 37 shows the package board 400 of FIG. 36 that top and bottom are reversed for convenience of explanation.

Since the first protecting layer 481 and the second protecting layer 482 according to an exemplary embodiment of the present disclosure are the same as the first protecting layer 181 and the second protecting layer 182 of FIG. 12, a detailed description makes reference to FIG. 12.

Although the methods of manufacturing the package board according to the first exemplary embodiment to the fourth exemplary embodiment of the present disclosure show and describe the case in which the package board is formed on one surface of the carrier substrate, the present disclosure is not limited thereto. That is, a process of manufacturing the package board on both surfaces of the carrier substrate according to a kind of the carrier substrate is performed. As a result, two package boards may be simultaneously formed. In addition, in the case in which the carrier substrate has a structure in which the carrier metal layer is laminated on the carrier core, when the carrier substrate and the package board are separated, only the carrier core may be removed. In addition, the carrier metal layer remaining on the package board may be removed or become the seed layer or the circuit pattern. As such, as the method of manufacturing the package board according to an exemplary embodiment of the present disclosure, the method known in a filed of circuit board may be used and may be partially changed according to the selection of those skilled in the art. Package

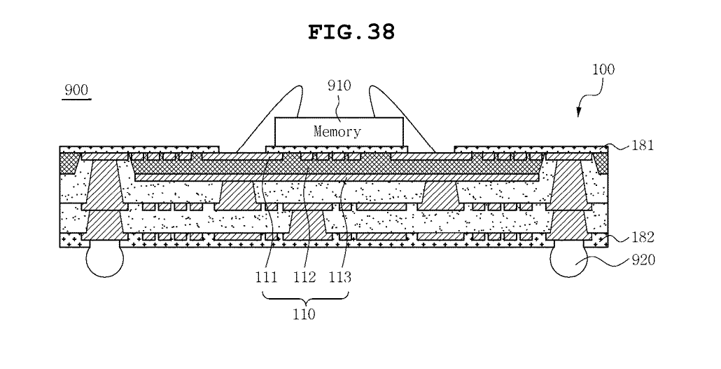

FIG. 38 is an illustrative view showing a package formed using the package board according to the first exemplary embodiment of the present disclosure.

Referring to FIG. 38, a package 900 may have an electronic component 910 mounted on the package board 100 and an external connecting terminal 920 formed thereon.

The package board 100 according to an exemplary embodiment of the present disclosure is the package board 100 of FIG. 1.

According to an exemplary embodiment of the present disclosure, the electronic component 910 is disposed on the first protecting layer 181 of the package board 100. For example, the electronic component 910 may be a memory device or an application process. However, the electronic component 910 is not limited to the memory device or the application process, and any kind of electronic component may be used as long as it is used in the package.

In addition, the electronic component 910 may be electrically connected to the upper electrode 111 of the capacitor 110 formed on the package board 100 through a wire. Although FIG. 38 shows and describes a case in which the electronic component 910 and the upper electrode 111 are connected by the wire, the present disclosure is not limited thereto. That is, the electronic component 910 and the upper electrode 111 may be connected by a known connection configuring unit such as a lead frame, a solder, or the like.

In addition, according to an exemplary embodiment of the present disclosure, the external connecting terminal 920 is formed on the second outer layer circuit pattern 170 exposed by the second protecting layer 182. The external connecting terminal 920 serves to electrically connect external configuring units such as the package, a main board, a part, and the like to the package 900 according to an exemplary embodiment of the present disclosure. For example, the external connecting terminal 920 may be a solder ball or a solder bump.

As such, in the package 900 using the package board 100 according to an exemplary embodiment of the present disclosure, since the electronic component 910 and the capacitor 110 are directly connected by the wire, a signal transmission distance is decreased, thereby making it possible to improve a signal transmission speed. In addition, since the capacitor 110 is formed on the whole surface of the package board 100, a degree of warpage is decreased, such that the electronic component 910 may be easily mounted and reliability of the package 900 may be improved. In addition, since the capacitor 110 is formed on the whole surface of the package board 100, reliability of signal transmission may be improved due to an increase in capacitance of the capacitor 110.

In an exemplary embodiment of the present disclosure, a case in which the package board 100 according to the first exemplary embodiment of the present disclosure is used in the package 900 has been described by way of example. However, the package 900 according to an exemplary embodiment of the present disclosure may be formed by using any one of the package boards according to the second exemplary embodiment to the fourth exemplary embodiment of the present disclosure as described above.

In addition, the package 900 according to an exemplary embodiment of the present disclosure may be used as a single package, but is not limited thereto. That is, although not shown as an exemplary embodiment of the present disclosure, the package 900 according to an exemplary embodiment of the present disclosure may be used for a package on package (POP) having different packages (not shown) and lamination structures.

Although the embodiments of the present disclosure have been disclosed for illustrative purposes, it will be appreciated that the present disclosure is not limited thereto, and those skilled in the art will appreciate that various modifications, additions and substitutions are possible, without departing from the scope and spirit of the disclosure.

Accordingly, any and all modifications, variations or equivalent arrangements should be considered to be within the scope of the disclosure, and the detailed scope of the disclosure will be disclosed by the accompanying claims.

1. A package board comprising:
an insulating layer;
a dielectric layer formed on the insulating layer;
a lower electrode formed on a whole surface of an upper surface of the insulating layer; and
an upper electrode formed on a whole surface of an upper surface of the dielectric layer.

2. The package board of claim 1, further comprising an inner layer circuit pattern formed in the insulating layer.

3. The package board of claim 2, further comprising a first via formed in the insulating layer to thereby electrically connect the inner layer circuit pattern and the lower electrode to each other.

4. The package board of claim 2, further comprising a first outer layer circuit pattern formed on the upper surface of the dielectric layer and having side surfaces formed to be spaced apart from the upper electrode.

5. The package board of claim 4, further comprising a second via formed in the insulating layer to thereby electrically connect the inner layer circuit pattern and the first outer layer circuit pattern, wherein the second via has side surfaces formed to be spaced apart from the lower electrode.

6. The package board of claim 5, wherein a portion of the insulating layer penetrates through the dielectric layer and the first outer layer circuit pattern connected to the second via is formed on the insulating layer penetrating through the dielectric layer.

7. The package board of claim 1, further comprising a second outer layer circuit pattern formed on a lower surface of the insulating layer.

8. The package board of claim 7, further comprising a third via formed in the insulating layer to thereby electrically connect the second outer layer circuit pattern and the lower electrode to each other.

9. The package board of claim 7, further comprising a fourth via formed in the insulating layer and the dielectric layer to thereby electrically connect the second outer layer circuit pattern and the upper electrode, wherein the fourth via has side surfaces formed to be spaced apart from the lower electrode.

10. The package board of claim 1, further comprising a protecting layer formed on the dielectric layer and the upper electrode and formed to expose a portion of the upper electrode.

11. The package board of claim 4, further comprising a protecting layer formed on the dielectric layer, the upper electrode, and the first outer layer circuit pattern, and formed to expose a portion of the first outer layer circuit pattern.

12. A package comprising:
an insulating layer;
a capacitor including a dielectric layer formed on the insulating layer, a lower electrode formed on a whole surface of an upper surface of the insulating layer, and an upper electrode formed on a whole surface of an upper surface of the dielectric layer;
a first protecting layer formed on the dielectric layer and the upper electrode; and
an electronic component disposed on the first protecting layer.

13. The package of claim 12, further comprising an inner layer circuit pattern formed in the insulating layer.

14. The package of claim 13, further comprising a first via formed in the insulating layer to thereby electrically connect the inner layer circuit pattern and the lower electrode to each other.

15. The package of claim 14, further comprising a first outer layer circuit pattern formed to be buried in the upper surface of the dielectric layer and having side surfaces formed to be spaced apart from the upper electrode.

16. The package of claim 15, further comprising a second via formed in the insulating layer to thereby electrically connect the inner layer circuit pattern and the first outer layer circuit pattern, wherein the second via has side surfaces formed to be spaced apart from the lower electrode.

17. The package of claim 16, wherein a portion of the insulating layer penetrates through the dielectric layer and the first outer layer circuit pattern connected to the second via is formed on the insulating layer penetrating through the dielectric layer.

18. The package of claim 12, further comprising a second outer layer circuit pattern formed on a lower surface of the insulating layer.

19. The package of claim 18, further comprising a third via formed in the insulating layer to thereby electrically connect the second outer layer circuit pattern and the lower electrode to each other.

20. The package of claim 18, further comprising a fourth via formed in the insulating layer and the dielectric layer to thereby electrically connect the second outer layer circuit pattern and the upper electrode, wherein the fourth via has side surfaces formed to be spaced apart from the lower electrode.

21. The package of claim 18, further comprising a second protecting layer formed below the insulating layer to thereby expose a portion of the second outer layer circuit pattern.

22. The package of claim 21, further comprising an external connecting terminal formed on the second outer layer circuit pattern exposed from the second protecting layer.

23. The package of claim 12, wherein the first protecting layer is formed to expose a portion of the upper electrode and the electronic component is electrically connected to the exposed upper electrode.

24. The package of claim 15, wherein the first protecting layer is formed on the dielectric layer, the upper electrode, and the first outer layer circuit pattern and formed to expose a portion of the first outer layer circuit pattern, and the electronic component is electrically connected to the exposed first outer layer circuit pattern.
